(19) United States
(12) Patent Application Publication
(10) Pub. No.: US 2008/0020327 A1
(43) Pub. Date: Jan. 24, 2008

(54) METHOD OF FORMATION OF A DAMASCENE STRUCTURE

(75) Inventors: Chih-Chao Yang, Poughkeepsie, NY (US); Wai-Kin Li, Beacon, NY (US); Yi-Hsiung Lin, Taipei (TW)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/458,499

(22) Filed: Jul. 19, 2006

(51) Int. Cl. G03F 7/26

(52) U.S. Cl. 430/313; 430/311

(57) ABSTRACT

A method in which during the formation of damascene features in a semiconductor structure, a planarization material is added to vias formed in the dielectric to protect the vias during subsequent lithographic processing. The planarization material preferred is a developable photosensitive material which can be exposed and developed to define the damascene features rather than etching as is conventional.

### BACKGROUND OF THE INVENTION

The present invention relates to the formation of damascene structures on a semiconductor wafer and especially to methods in which a developable photosensitive material is used to fill the vias during processing.

In damascene processing, the interconnect structure or wiring pattern is formed within a dielectric layer. Using known techniques a photoresist material is used to define the wiring pattern. The patterned photoresist acts as a mask through which a pattern of the dielectric material is removed by a subtractive etch process such as plasma etching or reactive ion etching. The etched openings are used to define wiring patterns in the dielectric layer. The wiring patterns are then filled with a metal using a filling technique such as electroplating, electroless plating, chemical vapor deposition, physical vapor deposition or a combination thereof. Excess metal can then be removed by chemical mechanical polishing through a process known as planarization.

In a single damascene process, via openings are provided in the dielectric layer and filled with a conducting metal, which is often referred to as metallization, to provide electrical contact between layers of wiring levels. In a dual damascene process, the via openings and the wiring pattern are both provided in the dielectric layer before filling with the conducting metal. Damascene processing followed by metallization is continued for each layer until the integrated circuit device is completed.

In the present processing of damascene structures, a so-called planarization material is used to fill the vias after the dielectric has been etched out. The planarization material also protects the vias during subsequent lithographic processing. A spin-on organic planarizing material (protective material) that is presently utilized is NFC 1400, available from JSR Corporation.

However, a problem with the use of spin-on organic planarizing material is that during the subsequent lithographic processing referred to above, the damascene structure can become oversized, undersized or otherwise nonconforming. The difficulties inherent in the use of the spin-on organic planarizing material are described below.

FIGS. 1A through 1G describe the conventional processing of damascene structures using a spin-on organic planarizing material. Referring to FIG. 1A, there is shown a semiconductor structure 10 being prepared for damascene structure. At this stage of the process, semiconductor structure 10 comprises semiconductor wafer 34, a previous wiring level which comprises dielectric 12, metallization 14 and capping layer 18, and the next wiring level which begins with dielectric 16. Dielectric 16 has been previously prepared by forming openings 20 therein by conventional lithographic and etching processing.

Referring now to FIG. 1B, spin-on organic planarizing material 22 is applied in the openings 20 and on the dielectric 16, followed by hard mask 24 (usually a low temperature oxide) and photoresist 26.

In FIG. 1C, the photoresist has been conventionally exposed and developed followed by definition of the hard mask 26 to form openings 28.

Thereafter, as shown in FIG. 1D, there is the spin-on organic planarizing material transfer etch in an H₂+O₂ plasma which removes the spin-on organic planarizing material 22 down to or slightly below the surface 30 of the dielectric 12.

Then, semiconductor structure 10 undergoes etching to remove dielectric 16 and enlarge openings 28. The dielectric 16 is etched by a combination of chemicals, for example CF₄, C₄F₈, NF₃, N₂, O₂, or NH₃, using the spin-on organic planarizing material 22A as a mask, and at the same time the hard mask layer 24 is completely removed from the wafer to result in the structure shown in FIG. 1E. Note that spin-on organic planarizing material 22 still remains in the vias at this time.

Referring now to FIG. 1F, the remaining spin-on organic planarizing material 22, 22A is stripped using an H₂+O₂ plasma.

Lastly, capping layer 18 is opened using a combination of chemicals, for example CHF₃, Ar, O₂, N₂ , to result in the semiconductor structure shown in FIG. 1G.

The processing of semiconductor structure 10 as just described is the ideal structure. The structure as it appears in reality is often quite different. Referring now to FIGS. 2, 3, and 4, there is illustrated the reality of what often happens in the spin-on organic planarizing material transfer etch step of FIG. 1D. In FIG. 2A, the spin-on organic planarizing material transfer etch has caused undercutting of the spin-on organic planarizing material at 36 resulting in an oversized critical dimension (CD) as shown in FIG. 2B.

In FIG. 3A, the spin-on organic planarizing material transfer etch has insufficiently etched the spin-on organic planarizing material at 38 resulting in an undersized CD as shown in FIG. 3B.

In FIG. 4A, the spin-on organic planarizing material transfer etch has caused profile damage of the spin-on organic planarizing material at 40 resulting in profile damage to the semiconductor structure 10 as shown in FIG. 4B.

In view of the foregoing, it would be desirable to have an improved process wherein the spin-on organic planarizing material transfer etch step can be modified so that the resulting semiconductor structure does not have an oversized CD, undersized CD or profile damage.

Accordingly, it is a purpose of the present invention to have a process wherein the spin-on organic planarizing material transfer etch step is modified to avoid an oversized CD, undersized CD or profile damage.

It is another purpose of the present invention to have a process wherein the spin-on organic planarizing material transfer etch step is modified to result in a semiconductor structure which is more mnaufacturable.

These and other purposes of the invention will become more apparent after referring to the following description of the invention in conjunction with the accompanying drawings.

### BRIEF SUMMARY OF THE INVENTION

The purposes of the invention have been achieved by providing, according to a first aspect of the invention, a method for the formation of features in a damascene process, the method comprising the steps of:

providing a semiconductor wafer having a dielectric layer thereon;

forming vias in the dielectric layer;

applying a developable photosensitive material to the dielectric layer so as to fill the vias and form a layer of developable photosensitive material on top of the dielectric layer;

applying a photoresist material to the layer of photosensitive material;

patterning the photoresist material so as to expose openings over portions of the developable photosensitive material layer;

exposing, developing and removing the exposed portions of developable photosensitive material layer so as to expose portions of the dielectric material;

etching the portions of the dielectric material through the openings; and

removing the remaining developable photosensitive material from the dielectric material to form damascene openings in the dielectric material.

According to a second aspect of the invention, there is provided a method for the formation of features in a damascene process, the method comprising the steps of:

providing a semiconductor wafer having a dielectric layer thereon;

forming vias in the dielectric layer;

applying a developable photosensitive material to the dielectric layer so as to fill the vias and form a layer of developable photosensitive material on top of the dielectric layer;

applying a layer of low temperature oxide to the layer of developable photosensitive material;

applying a photoresist material to the layer of low temperature oxide;

patterning the photoresist material so as to expose openings over portions of the low temperature oxide;

removing the portions of low temperature oxide in the openings so as to expose openings over portions of the developable photosensitive material layer;

exposing, developing and removing the exposed portions of developable photosensitive material layer so as to expose portions of the dielectric material;

etching the portions of the dielectric material through the openings;

removing the remaining developable photosensitive material from the dielectric material to form damascene openings in the dielectric material.

### BRIEF DESCRIPTION OF THE DRAWINGS

The features of the invention believed to be novel and the elements characteristic of the invention are set forth with particularity in the appended claims. The Figures are for illustration purposes only and are not drawn to scale. The invention itself, however, both as to organization and method of operation, may best be understood by reference to the detailed description which follows taken in conjunction with the accompanying drawings in which:

FIGS. 1A through 1G illustrate an idealized conventional process for forming a semiconductor structure using a protective material.

FIGS. 2A and 2B illustrate the actual structure and the resulting lithographic structure that is formed according to the transfer etch process described with reference to FIG. 1D resulting in an oversized CD.

FIGS. 3A and 3B illustrate the actual structure and the resulting lithographic structure that is formed according to the transfer etch process described with reference to FIG. 1D resulting in an undersized CD.

FIGS. 4A and 4B illustrate the actual structure and the resulting lithographic structure that is formed according to the transfer etch process described with reference to FIG. 1D resulting in profile damage.

FIGS. 5A through 5D illustrate a first embodiment of the present invention wherein the spin-on organic planarizing material described with reference to the conventional process in FIGS. 1A through 1G is replaced with a developable photosensitive material.

FIGS. 6A through 6D illustrate a second embodiment of the present invention wherein the spin-on organic planarizing material described with reference to the conventional process in FIGS. 1A through 1G is replaced with a developable photosensitive material.

FIGS. 7A through 7D illustrate a third embodiment of the present invention wherein the spin-on organic planarizing material described with reference to the conventional process in FIGS. 1A through 1G is replaced with a developable photosensitive material.

FIG. 8 is a flow chart illustrating the methods according to the present invention.

### DETAILED DESCRIPTION OF THE INVENTION

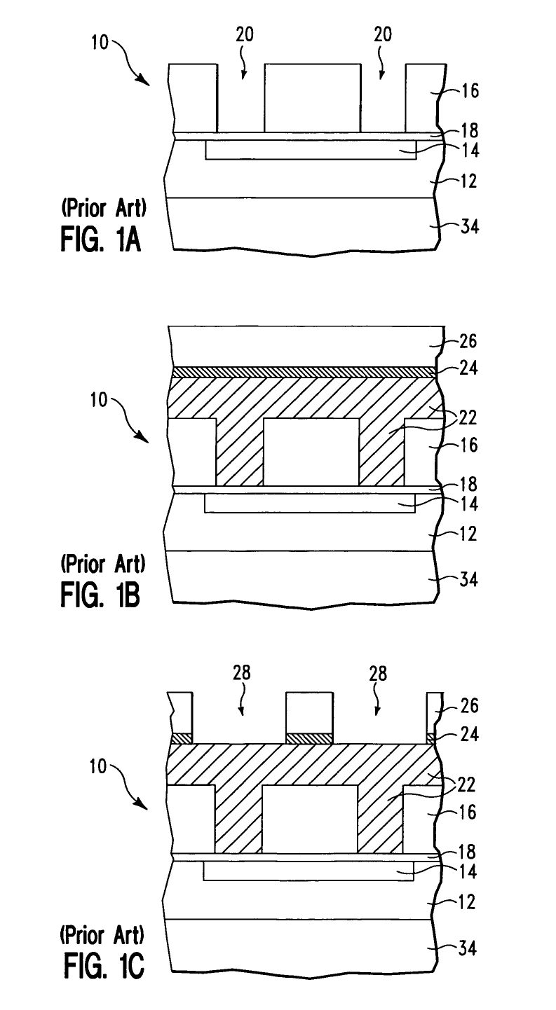

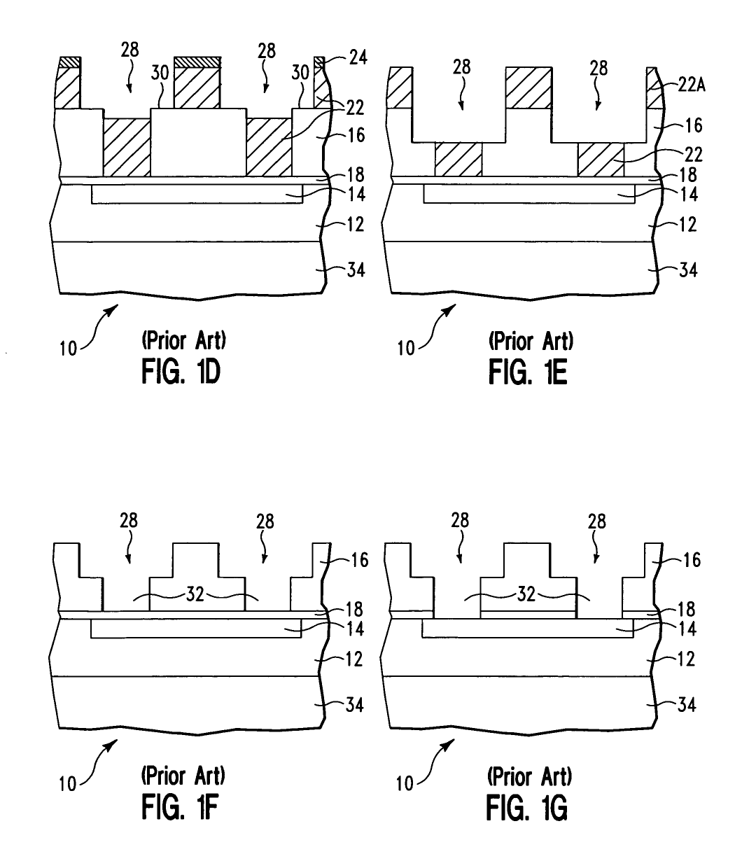

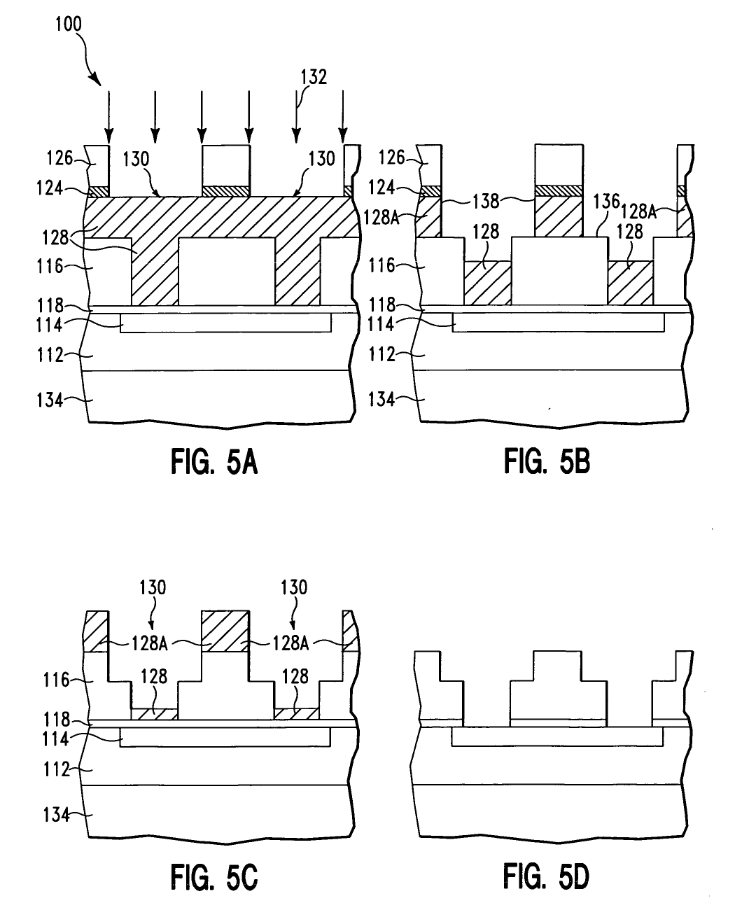

Referring now to FIGS. 5A through 5D, a first preferred embodiment of the invention will be described. The semiconductor structure shown in FIG. 5A comprises semiconductor wafer 134, a previous wiring level which comprises dielectric 112, metallization 114 and capping layer 118, and the next wiring level which begins with dielectric 116. Further shown in FIG. 5A is a spin-on organic planarizing material which in this case is a developable photosensitive material 128, hard mask 124 and photoresist 126. The semiconductor structure 100 shown in FIG. 5A is prepared according to the methodology of FIGS. 1A through 1C except that the first preferred embodiment of the semiconductor structure 100 includes a developable photosensitive material 128 instead of the spin-on organic planarizing material 22 shown in FIGS. 1B and 1C.

The developable photosensitive material is not what one skilled in the art would call a photoresist. The developable photosensitive material is a wet developable gap fill material that can be used to planarize topography and vias of various sizes and can also be used as an easily removable substrate protection layer. The developable photosensitive material should have the following properties: it is a highly planarizing material, compatible with commercial photoresists, and easily removed from the vias by wet etching after exposure. The imaging properties of the developable photosensitive material are not as good as a photoresist and it should be fast developable because it is applied thicker than a photoresist. It should have reflectivity control similar to that of a bottom antireflective compound (BARC). A particularly preferred developable photosensitive material is a copolymer or terpolymer containing acrylate, maleimide, lactone and admantane with a photo sensitive component or components. The material is a wet developable gap fill material that is soluble in typical resist developer, therefore eliminating the need to remove wafers from the coat/developer track and transferring them to the dry etch bay. The develop rate is controllable by the bake temperature and/or bake time, with a wide bake range available depending on processing needs.

Still referring to FIG. 5A, the semiconductor structure 100 is blanket exposed to suitable radiation 132 to cause the developable photosensitive material 128 in openings 130 to be exposed to the radiation 132. In the case of the EXP04065 material, this radiation is 10-25 millijoules (mj) with focus between −0.2 and +0.2 microns. Then, the developable photosensitive material 128 is developed by application of a developer such as water, water mixed with a surfactant in an amount less than 30 weight % or tetramethylammonium hydroxide (TMAH) to cause removal of the developable photosensitive material 128 within openings 130 and thus deepen the openings down to approximately the surface 136, or even slightly below the surface 136, of the dielectric 116 as shown in FIG. 5B.

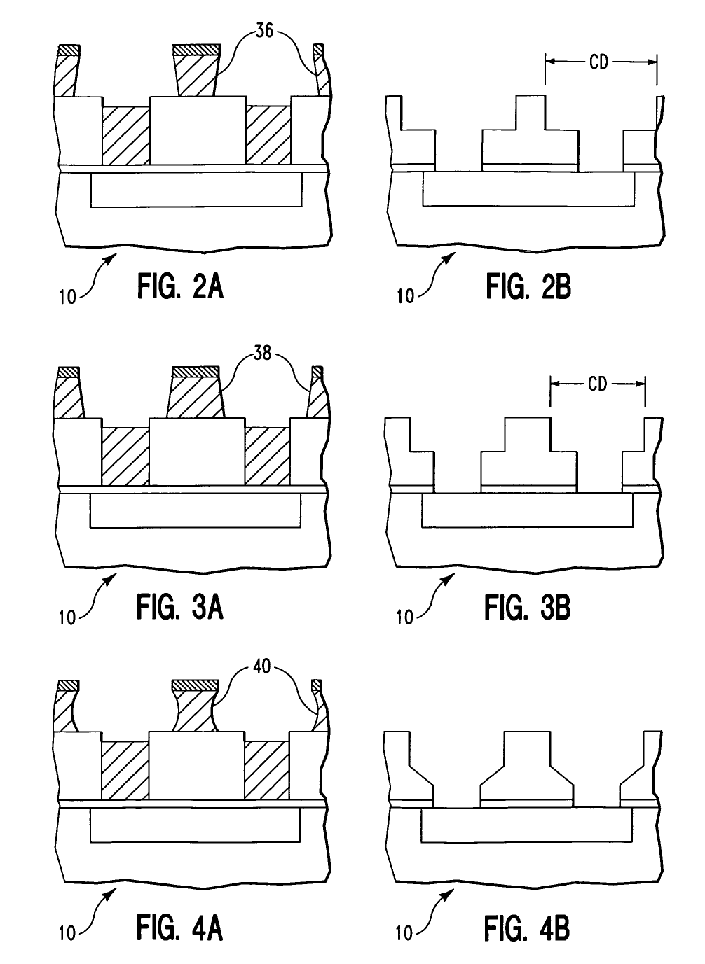

An advantage of the present invention is vertical surfaces 138 will be formed on the pillars 128A of the developable photosensitive material 128 as shown in FIG. 5B. The semiconductor structure 100 shown in FIG. 5B should be compared to the semiconductor structures 10 shown in FIGS. 2 to 4 to appreciate the advantages of the present invention.

The process continues by conventionally etching the dielectric 116 to remove it and deepen the openings 130 as shown in FIG. 5C. Some of the developable photosensitive material 128 may remain in the vias as shown in FIG. 5C. Further in this process step, the photoresist 126 and hardmask 124 are removed leaving pillars of developable photosensitive material 128A.

Thereafter, the remaining developable photosensitive material 128A, 128 is stripped using an H₂+O₂ plasma and the capping layer 118 is opened to result in the structure shown in FIG. 5D.

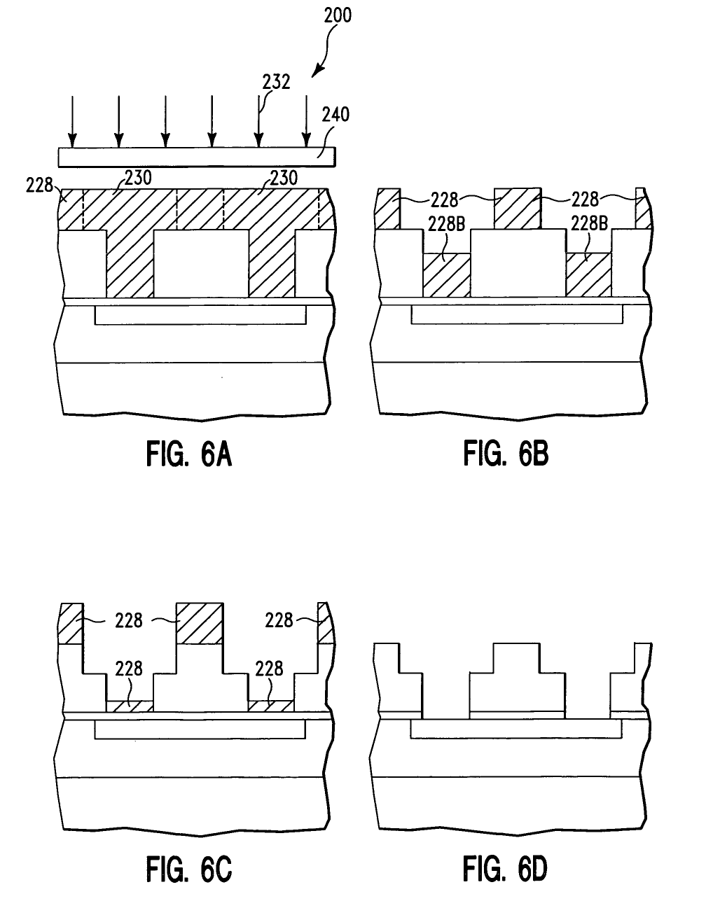

Referring now to FIGS. 6A through 6D, a second preferred embodiment of the present invention will be discussed. The processing of semiconductor structure 200 is similar to that of semiconductor structure 100 in FIGS. 5A through 5D. Semiconductor structure 200 in FIG. 6A, however, does not require a hard mask (124 in FIGS. 5A and 5B). In FIG. 6A, developable photosensitive material 228 is applied to the semiconductor structure 200 as was done with respect to semiconductor structure 100 in FIG. 5A. Then, a photomask 240 is placed close to the surface of the developable photosensitive material 228 and a suitable radiation (10-25 millijoules (mj) with focus between −0.2 and +0.2 microns) is applied through the photomask 240.

As used in photolithography, a photomask is typically a transparent fused quartz blank covered with a pattern defined with chrome metal as the absorbing film. In the present case, the photomask is used at wavelengths of 193 nm. Photomasks have also been developed for other forms of radiation such as 157 nm, 13.5 nm (EUV), X-ray, electrons and ions, but these may require different materials for the substrate and the pattern film. The photomask 240 allows radiation 232 to exit the mask only where it is desired, in this case areas 230 of the developable photosensitive material 228.

The photomask 240 is then removed and developer (such as water, water mixed with a surfactant in an amount less than 30 weight % or tetramethylammonium hydroxide (TMAH)) is applied to develop and remove areas 230 of the developable photosensitive material 228 as shown in FIG. 6B. The processing of FIGS. 6B through 6D then continues the same as described with respect to FIGS. 5B though 5D, except that there is no hard mask or photoresist to remove, to result in the structure shown in FIG. 6D.

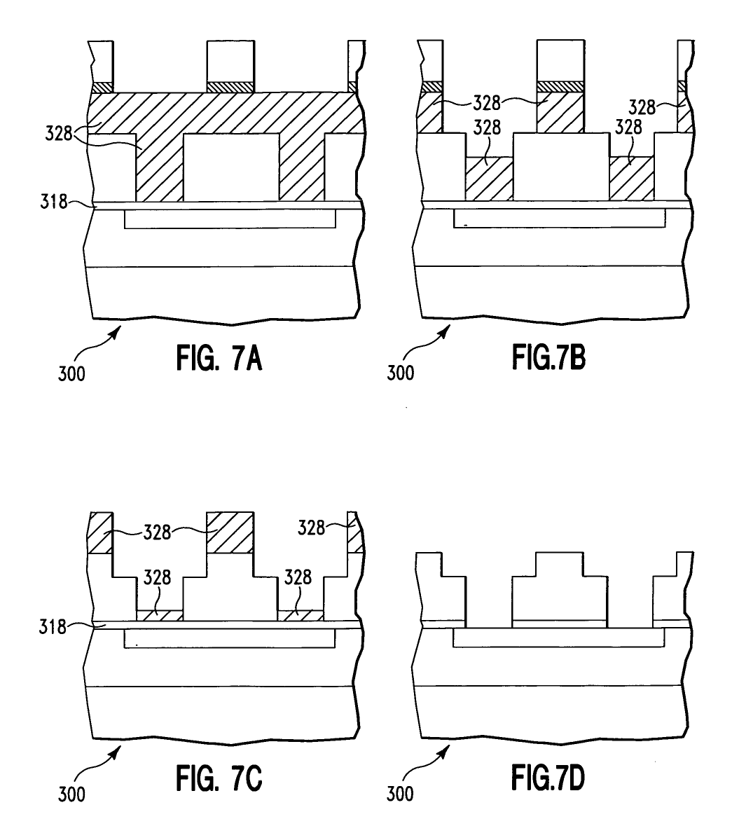

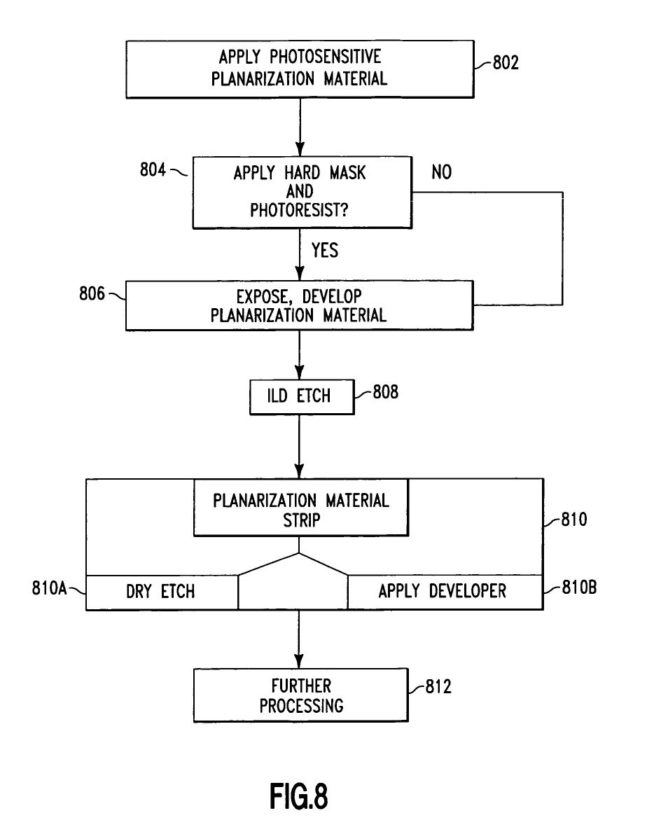

Referring now to FIGS. 7A through 7D, a third preferred embodiment of the present invention will now be described. The processing of the semiconductor structure 300 shown in FIGS. 7A through 7D is the same as the processing of semiconductor structure 100 in FIGS. 5A through 5D except that any remaining developable photosensitive material, such as 328 shown in FIG. 7C, is removed by reapplying the developer (such as water, water mixed with a surfactant in an amount less than 30 weight % or tetramethylammonium hydroxide (TMAH)) that was first applied in FIG. 7A to result in the structure shown in FIG. 7B. In the previous preferred embodiments of the present invention, any remaining developable photosensitive material was removed by an H₂+O₂ plasma. Reapplication of the developer to remove any remaining developable photosensitive material 328 can be more desirable than an H₂+O₂ plasma because it eliminates any possible charging issues that would occur from plasma related processing. Capping layer 318 is then conventionally opened.

FIG. 8 is a flow chart illustrating the various embodiments of the present invention. In step 802, the developable photosensitive material is applied to the wafer. In step 804, a hard mask and then photoresist (to pattern the hard mask) is optionally applied and patterned to form openings through which the developable photosensitive material is exposed and developed in step 806. Alternatively, a photomask may be positioned with respect to the developable photosensitive material, thereby rendering unnecessary the application of the hard mask and photoresist in step 804, and then the developable photosensitive material is exposed and developed to form openings. Thereafter in step 808, the ILD is etched to enlarge the previously defined openings. The developable photosensitive material is then stripped in step 810. Stripping may be by a dry etch (step 810A) or reapplication of the developer (step 810B). Finally, the wafer is sent for further processing in step 812.

In the preferred embodiments of the invention above, the dielectric layers could comprise, for example, SiCOH, SiLK (a poly(arylene ether) available from Dow Chemical), JSR (a spin-on silicon-carbon containing polymer material from JSR Corporation), SiO₂ or Si₃N₄; the metallization could comprise Cu, Al, Cu(Al) or W; and the capping layer could comprise SiC(N,H), SiO₂, Si₃N₄ or CoWP.

It will be apparent to those skilled in the art having regard to this disclosure that other modifications of this invention beyond those embodiments specifically described here may be made without departing from the spirit of the invention. Accordingly, such modifications are considered within the scope of the invention as limited solely by the appended claims.

What is claimed is:

1. A method for the formation of features in a damascene process, the method comprising the steps of:
(a) providing a semiconductor wafer having a dielectric layer thereon;
(b) forming vias in the dielectric layer;
(c) applying a developable photosensitive material to the dielectric layer so as to fill the vias and form a layer of developable photosensitive material on top of the dielectric layer;
(d) applying a photoresist material to the layer of photosensitive material;
(e) patterning the photoresist material so as to expose openings over portions of the developable photosensitive material layer;
(f) exposing, developing and removing the exposed portions of developable photosensitive material layer so as to expose portions of the dielectric material;
(g) etching the portions of the dielectric material through the openings; and
(h) removing the remaining developable photosensitive material from the dielectric material to form damascene openings in the dielectric material.

2. The method of claim 1 wherein there is a capping layer underneath the dielectric layer and further comprising the step (i) of removing the capping layer from the openings in the dielectric layer.

3. The method of claim 1 wherein the developable photosensitive material comprises copolymers or terpolymers containing acrylate, maleimide, lactone and admantane with a photosensitive component.

4. The method of claim 3 wherein the developable photosensitive material further comprises an antireflective compound.

5. The method of claim 1 wherein in step (h), removing is by stripping with a plasma.

6. The method of claim 5 wherein the plasma is an H₂+O₂ plasma.

7. The method of claim 1 wherein in step (h), removing is by applying a developer suitable to dissolve the developable photosensitive material.

8. A method for the formation of features in a damascene process, the method comprising the steps of:
(a) providing a semiconductor wafer having a dielectric layer thereon;
(b) forming vias in the dielectric layer;
(c) applying a developable photosensitive material to the dielectric layer so as to fill the vias and form a layer of developable photosensitive material on top of the dielectric layer;
(d) applying a layer of low temperature oxide to the layer of developable photosensitive material;
(e) applying a photoresist material to the layer of low temperature oxide;
(f) patterning the photoresist material so as to expose openings over portions of the low temperature oxide;
(g) removing the portions of low temperature oxide in the openings so as to expose openings over portions of the developable photosensitive material layer;
(h) exposing, developing and removing the exposed portions of developable photosensitive material layer so as to expose portions of the dielectric material;
(i) etching the portions of the dielectric material through the openings;
(j) removing the remaining developable photosensitive material from the dielectric material to form damascene openings in the dielectric material.

9. The method of claim 8 wherein there is a capping layer underneath the dielectric layer and further comprising the step (i) of removing the capping layer from the openings in the dielectric layer.

10. The method of claim 8 wherein the developable photosensitive material comprises copolymers or terpolymers containing acrylate, maleimide, lactone and admantane with a photosensitive component.

11. The method of claim 10 wherein the developable photosensitive material further comprises an antireflective compound.

12. The method of claim 8 wherein in step (h), removing is by stripping with a plasma.

13. The method of claim 12 wherein the plasma is an H₂+O₂ plasma.

14. The method of claim 8 wherein in step (h), removing is by applying a developer suitable to dissolve the developable photosensitive material.
